(19) United States
(12) Patent Application Publication
(10) Pub. No.: US 2013/0101056 A1
(43) Pub. Date: Apr. 25, 2013

(54) RECEIVER CIRCUIT AND SYSTEM INCLUDING P-TYPE SENSE AMPLIFIER

(71) Applicant: Samsung Electronics Co., ltd., Suwon-si (KR)

(72) Inventors: Min-Su Ahn, Suwon-si (KR); Byong-Mo MOON, Seoul (KR)

(21) Appl. No.: 13/657,942

(22) Filed: Oct. 23, 2012

Related U.S. Application Data
(60) Provisional application No. 61/551,072, filed on Oct. 25, 2011.

(30) Foreign Application Priority Data
Sep. 24, 2012 (KR) 10-2012-0105697

(51) Int. Cl. H04B 3/00; H04L 27/04; H03F 3/217; H04L 27/08

(52) U.S. Cl. 375/257; 375/316; 375/295; 330/251

(57) ABSTRACT

A receiver circuit includes a first p-channel metal oxide semiconductor (PMOS) transistor, an input circuit, and an amplifier. The first PMOS transistor is configured to apply a power supply voltage to a power node in response to a clock signal. The input circuit is coupled to the power node, and configured to receive the power supply voltage, and the input circuit includes a plurality of PMOS transistors configured to generate a first sensing signal in response to an input signal and configured to generate a second sensing signal in response to at least one reference signal. The amplifier is configured to amplify the first sensing signal and the second sensing signal to generate a first output signal and a second output signal.

### CROSS-REFERENCE TO RELATED APPLICATION

This U.S. non-provisional application claims priority under 35 USC §119 to U.S. Provisional Application No. 61/551,072 filed on Oct. 25, 2011 in the USPTO, and Korean Patent Application No. 10-2012-0105697, filed on Sep. 24, 2012 in the Korean Intellectual Property Office (KIPO), the contents of which are herein incorporated by reference in their entirety.

### BACKGROUND

Example embodiments relate generally to integrated circuits for signal transfer, and more particularly to a receiver circuit and a system including a p-type sense amplifier.

Receiver circuits are implemented, in general, with an n-type sense amplifier that senses an input signal using n-channel metal oxide semiconductor (NMOS) transistors. The sensitivity of the n-type sense amplifier may be degraded depending on the pattern of the input signal. Furthermore the n-type sense amplifier may not sense the input signal at all in the worst a worst case.

### SUMMARY

Some example embodiments provide a receiver circuit for enhancing sensitivity to an input signal that swings within a relatively narrow range near a ground voltage, for example, under 1V.

Some example embodiments provide a system including a transmitter circuit for transferring an input signal that swings within a relatively narrow range near a ground voltage and a receiver circuit for sensing the input signal with enhanced sensitivity.

According to example embodiments, a receiver circuit includes a first p-channel metal oxide semiconductor (PMOS) transistor, an input circuit and an amplifier. The first PMOS transistor applies a power supply voltage to a power node in response to a clock signal. The input circuit is coupled to the power node to receive the power supply voltage, and the input circuit includes a plurality of PMOS transistors configured to generate a first sensing signal in response to an input signal and configured to generate a second sensing signal in response to at least one reference signal. The amplifier is configured to amplify the first sensing signal and the second sensing signal and to generate a first output signal representing a first of two binary values, and to generate a second output signal representing a second of the two binary values opposite to the first binary values.

According to example embodiments, a system includes a transmitter circuit including a transmission driver configured to drive a first node in response to a pull up signal and a pull down signal, and a receiver circuit configured to receive an input signal at a terminal that is coupled to the first node through a signal line. The receiver circuit includes a switching p-channel metal oxide semiconductor (PMOS) transistor configured to apply a power supply voltage to a power node in response to a clock signal, an input circuit coupled to the power node to, and configured to receive the power supply voltage, the input circuit including a plurality of PMOS transistors configured to generate a first sensing signal and a second sensing signal in response to the input signal and at least one reference signal, the first sensing signal corresponding to the input signal, the second sensing signal corresponding to the at least one reference signal, and an amplifier configured to amplify the first sensing signal and the second sensing signal, and to generate a first output signal and a second output signal opposite to the first output signal.

According to example embodiments, a semiconductor device includes a first PMOS transistor, a second PMOS transistor, a third PMOS transistor, and a first amplifier. The first PMOS transistor is configured to apply a power supply voltage to a first node in response to a first clock signal. The second PMOS transistor is coupled to the first node and is configured to generate a first sensing signal at a second node in response to an input signal. The third PMOS transistor is coupled to the first node and is configured to generate a second sensing signal at a third node in response to a first reference signal. The first amplifier is configured to amplify the first and second sensing signals, and configured to generate first and second output signals in response to the first and second sensing signals, respectively. The first output signal has a voltage representing a first binary values and the second output signal has a voltage representing a second binary values, opposite of the first binary values.

### BRIEF DESCRIPTION OF THE DRAWINGS

Example embodiments will be more clearly understood from the following detailed description taken in conjunction with the accompanying drawings.

FIG. 1 is a diagram illustrating a receiver circuit including a p-type sense amplifier according to example embodiments.

FIG. 2 is a diagram illustrating a system according to example embodiments.

FIG. 3 is a diagram illustrating a pull up operation of a transmitter circuit in the system of FIG. 2.

FIG. 4 is a diagram illustrating a pull down operation of a transmitter circuit in the system of FIG. 2.

FIG. 5 is a diagram illustrating voltage levels of an input signal received by the system of FIG. 2.

FIG. 6 is a circuit diagram illustrating an example of an amplifier in the receiver circuit of FIG. 1 according to example embodiments.

FIG. 7 is a diagram illustrating a receiver circuit according to another example embodiments.

FIG. 8 is a diagram illustrating an example operation of a receiver circuit according to example embodiments.

FIG. 9 is a circuit diagram illustrating another example of an amplifier in the receiver circuit of FIG. 1 according to example embodiments.

FIG. 10 is a diagram illustrating a p-type sense amplifier according to another example embodiments.

FIG. 11 is a diagram illustrating an example operation of a receiver circuit according to example embodiments.

FIG. 12 is a diagram illustrating sensing margins of receiver circuits according to example embodiments.

FIGS. 13 and 14 are diagrams illustrating systems of performing bi-directional communication according to example embodiments.

FIG. 15 is a diagram illustrating a multi-channel system according to example embodiments.

FIGS. 16 and 17 are diagrams illustrating systems of providing reference voltages according to example embodiments.

FIG. 18 is a diagram illustrating an operation of the system of FIG. 17 according to example embodiments.

FIG. 19 is a diagram illustrating a system of performing a double data rate (DDR) transfer according to example embodiments.

FIGS. 20 and 21 illustrate semiconductor packages according to example embodiments.

FIG. 22 is a block diagram illustrating an electronic device according to example embodiments.

FIG. 23 is a block diagram illustrating an interface employable in the electronic device of FIG. 22 according to example embodiments.

### DETAILED DESCRIPTION OF THE EMBODIMENTS

Various example embodiments will be described more fully hereinafter with reference to the accompanying drawings, in which some example embodiments are shown. The present disclosure may, however, be embodied in many different forms and should not be construed as limited to the example embodiments set forth herein. In the drawings, the sizes and relative sizes of layers and regions may be exaggerated for clarity. Like numerals refer to like elements throughout.

It will be understood that, although the terms first, second, third etc. may be used herein to describe various elements, components, regions, layers and/or sections, these elements, components, regions, layers and/or sections should not be limited by these terms. Unless indicated otherwise, these terms are used to distinguish one element, component, region, layer and/or section from another. Thus, a first element, component, region, layer and/or section discussed below could be termed a second element, component, region, layer and/or section without departing from the teachings of the present disclosure. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present disclosure. As used herein, the singular forms “a,” “an” and “the” are intended to include the plural forms as well, unless the context clearly indicates otherwise. It will be further understood that the terms such as “comprises,” “comprising,” “includes,” and/or “including,” when used in this specification, specify the presence of stated features, integers, steps, operations, elements, and/or components, but do not preclude the presence or addition of one or more other features, integers, steps, operations, elements, components, and/or groups thereof.

It should also be noted that in some alternative implementations, the functions/acts noted in the blocks may occur out of the order noted in the flowcharts. For example, two blocks shown in succession may in fact be executed substantially concurrently or the blocks may sometimes be executed in the reverse order, depending upon the functionality/acts involved.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

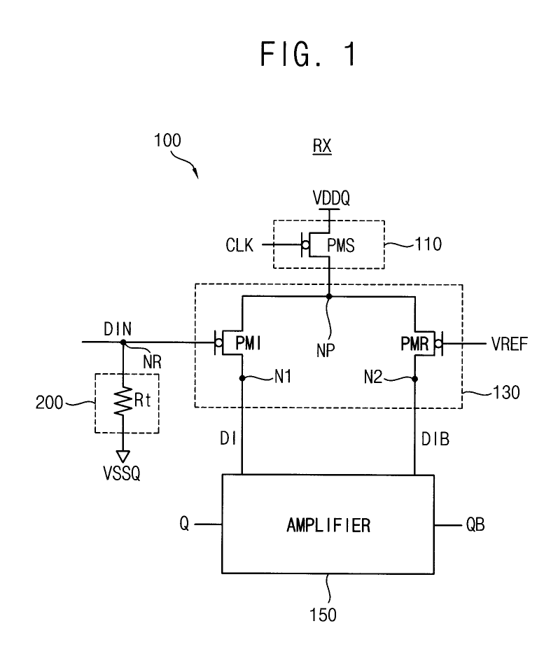

FIG. 1 is a diagram illustrating a receiver circuit including a p-type sense amplifier according to example embodiments.

Referring to FIG. 1, a receiver circuit RX includes a p-type sense amplifier 100. The p-type sense amplifier 100 may include a switching circuit 110, an input circuit 130 and an amplifier 150.

The switching circuit 110 may include a switching p-channel metal oxide semiconductor (PMOS) transistor PMS. The switching PMOS transistor PMS applies a power supply voltage VDDQ to a power node NP in response to a clock signal CLK. The switching PMOS transistor PMS is turned off during a first half-cycle corresponding to logic high level of the clock signal CLK to float the power node NP. The switching PMOS transistor PMS is turned on during a second half-cycle corresponding to logic low level of the clock signal CLK to apply the power supply voltage VDDQ to the power node NP. Accordingly the p-type sense amplifier 100 may repeat the sensing operation during the first half-cycle and the floating operation during the second half-cycle.

The input circuit 130 is coupled to the power node NP to receive the power supply voltage VDDQ. The input circuit 130 includes a plurality of PMOS transistors PMI and PMR that generate a first sensing signal DI and a second sensing signal DIB in response to an input signal DIN and at least one reference voltage VREF, such that the first sensing signal DI corresponds to the input signal DIN and the second sensing signal DIB corresponds to the at least one reference voltage VREF.

The amplifier 150 amplifies the first sensing signal DI and the second sensing signal DIB to generate a first output signal Q and a second output signal QB. The first output signal Q may have a first of two binary values (i.e., a logic high level and a logic low level) and the second output signal QB may have a second of two binary values opposite to the first binary values.

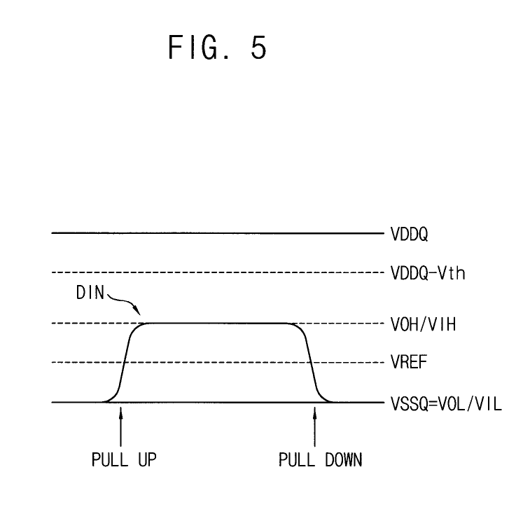

The receiver circuit RX may further include a ground termination circuit 200 coupled between a ground voltage VSSQ and a reception node NR receiving the input signal DIN. The ground termination circuit 200 may include at least one resistor Rt. For example, the input signal DIN may swing between a low voltage level VOL (Hereinafter, or VIL) and a high voltage level VOH (Hereinafter, or VIH), as will be described with reference to FIG. 5. The low voltage level VOL may correspond to the ground voltage VSSQ (e.g., 0 V) and the high voltage level VOH may be lower than the power supply voltage VDDQ.

In some example embodiments, the input circuit 130 may generate the second sensing signal DIB based on the one reference voltage VREF as illustrated in FIG. 1. In other example embodiments, the input circuit 130a may generate the second sensing signal DIB based on a plurality of reference voltages VREF1 and VREF2 as illustrated in FIG. 10.

For example, when the one reference voltage VREF is used, the input circuit 130 may include an input PMOS transistor PMI and a reference PMOS transistor PMR.

The input PMOS transistor PMI is coupled between the power node NP and a first node N1 generating the first sensing signal DI, and a gate of the input PMOS transistor PMI receives the input signal DIN. The reference PMOS transistor PMR is coupled between the power node NP and a second node N2 generating the second sensing signal DIB, and a gate of the reference PMOS transistor PMR receives the reference voltage VREF. The reference voltage VREF may have an average voltage level VA of the low voltage level VOL and the high voltage level VOH of the input signal DIN.

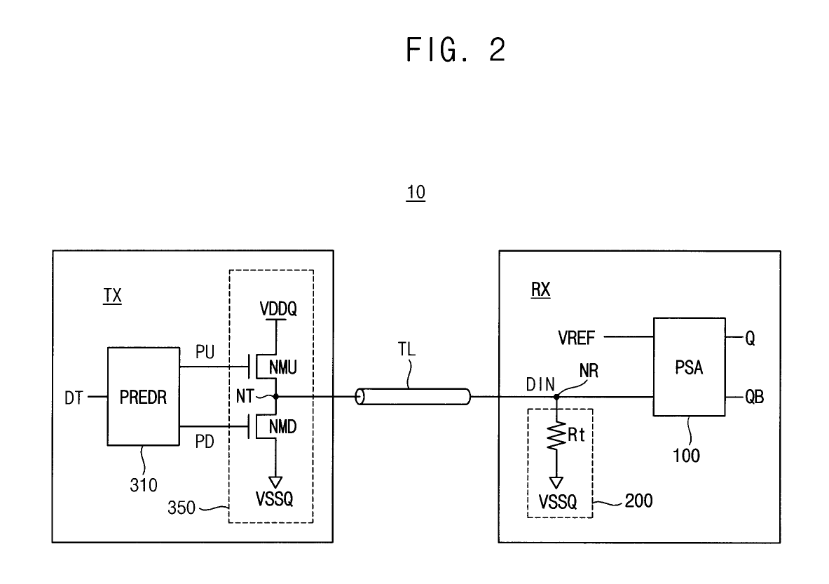

FIG. 2 is a diagram illustrating a system according to example embodiments.

Referring to FIG. 2, a system 10 may include a transmitter circuit TX and a receiver circuit RX that are coupled with each other through a transmission line TL. The transmitter circuit TX and the receiver circuit RX may be included in respective devices. For example, the transmitter circuit TX may be integrated in one chip and the receiver circuit RX may be integrated in another chip. The transmission line TL may be an arbitrary conductive line and may be a portion of a bus system. For example, the transmission line TL may be formed in or on a printed circuit board (PCB).

The transmitter circuit TX includes a transmission driver 350 that drives a transmission node NT in response to a pull up signal PU and a pull down signal PD. The transmitter circuit TX may further include a pre-driver (PREDR) 310 that outputs the pull up signal PU and the pull down signal PD based on a transmission signal DT. The pull up signal PD and the pull down signal PD are signals transitioning complementarily between a logic high level and a logic low level.

The receiver circuit RX receives an input signal DIN at a reception node NR that is coupled to the transmission node NT through the transmission line TL. As described with reference to FIG. 1, the receiver circuit may include the p-type sense amplifier 100 and the ground termination circuit 200. The p-type sense amplifier 100 may include the switching circuit 110, the input circuit 130, and the amplifier 150. The switching circuit 110 may include the switching PMOS transistor PMS. The switching PMOS transistor PMS applies the power supply voltage VDDQ to the power node NP in response to the clock signal CLK. The input circuit 130 is coupled to the power node NP to receive the power supply voltage VDDQ. The input circuit 130 includes the PMOS transistors PMI and PMR that generate the first sensing signal DI and the second sensing signal DIB in response to the input signal DIN and at least one reference voltage VREF, such that the first sensing signal DI corresponds to the input signal DIN and the second sensing signal DIB corresponds to the at least one reference voltage VREF. The amplifier 150 amplifies the first sensing signal DI and the second sensing signal DIB to generate the first output signal Q and the second output signal QB. In one embodiment, the at least one reference voltage VREF may be generated by a reference generation circuit (not shown) included in one device which is formed the receiver circuit RX or included in another device which is formed the receiver circuit RX.

As illustrated in FIG. 2, the transmission driver 350 may include a pull up n-channel metal oxide semiconductor (NMOS) transistor NMU and a pull down NMOS transistor NMD, which are coupled between the power supply voltage VDDQ and the ground voltage VSSQ. The power supply voltage VDDQ and the ground voltage VSSQ of the transmitter circuit TX may be the same as or different from those of the receiver circuit RX.

The conventional transmission driver includes a PMOS transistor as a pull up driver and an NMOS transistor as a pull down driver. The hole mobility, that is, the carrier mobility of the PMOS transistor is smaller than the electron mobility, that is, the carrier mobility of the NMOS transistor, the PMOS transistor has the lower operation speed and the larger occupation size than the NMOS transistor.

Accordingly, by implementing the NMOS transistor NMU as the pull up driver of the transmission driver 350 as illustrated in FIG. 2, the transmitter circuit TX may have a decreased size and an increased operational speed. When the pull up driver is implemented with the NMOS transistor, the transmitter driver 350 may operate at the higher frequency than the conventional transmitter circuit including the pull up PMOS transistor.

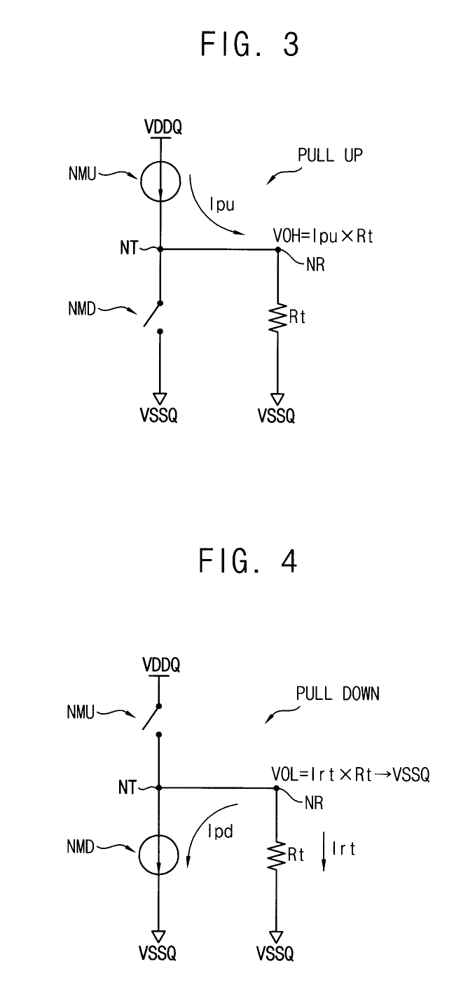

FIG. 3 is a diagram illustrating a pull up operation of a transmitter circuit in the system of FIG. 2, FIG. 4 is a diagram illustrating a pull down operation of a transmitter circuit in the system of FIG. 2 and FIG. 5 is a diagram illustrating voltage levels of an input signal received by the system of FIG. 2.

Referring to FIGS. 3 and 5, in a pull up operation, the pull up NMOS transistor NMU is turned on in response to the pull up signal PU of the logic high level and the pull down NOMS transistor NMD is turned off in response to the pull down signal PD of the logic low level, to pull up the voltage at the transmission node NT. The maximum output voltage at the transmission node NT by the transmission driver 350 is limited to VDDQ-Vth, where Vth is the threshold voltage of the pull up NMOS transistor NMU. The pull up NMOS transistor NMU functions as a current source during the pull up operation. A pull up current Ipu flowing through the pull up NMOS transistor may be determined depending on VDDQ−VOH as Expression 1, where k1 and r1 are values determined based on the characteristics of the pull up NMOS transistor NMU.

Ipu=k1*(VDDQ−VOH)^{r1}=>k1*(Vth)^{r1} Expression 1

The pull up current Ipu is increased as the high voltage level VOH at the reception node NR is increased and the pull up current Ipu reaches k1*(Vth)^{r1}. The high voltage level VOH of the input signal DIN may be determined as Ipu*Rt depending on the pull up current Ipu and the termination resistor Rt. The high voltage level VOH may be increased by increasing at least one of the pull up current Ipu and the termination resistor Rt. The amount of the pull up current Ipu and the resistance value of the termination resistor Rt may be determined properly considering the integrity characteristic of the signals transferred through the transmission line TL. The amount of the pull up current Ipu may be changed according to the variations of the manufacturing process, the operational voltage and the operational temperature, and the amount of the pull up current Ipu may be determined by adjusting the width of the pull up PMOS transistor NMU.

Referring to FIGS. 4 and 5, in a pull down operation, the pull up NMOS transistor NMU is turned off in response to the pull up signal PU of the logic low level and the pull down NOMS transistor NMD is turned on in response to the pull down signal PD of the logic high level, to pull down the voltage at the transmission node NT.

The termination current Irt flows through the termination resistor Rt to the ground voltage VSSQ and at the same time the pull down currents Ipd flows through the pull down NMOS transistor NMD to the ground voltage VSSQ when the pull down NMOS transistor is turned on. As a result, the voltage at the reception node NR, that is, the low voltage level VOL reaches the ground voltage VSSQ. The pull down current Ipd may be determined depending on VOL−VSSQ as Expression 2, where k2 and r2 are values determined based on the characteristics of the pull down NMOS transistor NMD.

Ipd=k2*(VOL−VSSQ)^{r2}=>0 Expression 2

The pull down NMOS transistor NMD is turned off when the low voltage level is decreased below the threshold voltage of the pull down NMOS transistor NMD. Even though the pull down current Ipd becomes zero at the low voltage level VOL higher than the ground voltage VSSQ, the low voltage level VOL reaches the ground voltage VSSQ (e.g., 0V) ultimately due to the termination current Irt.

For example, the reference voltage VREF may have the average voltage level VA of the ultimate high voltage level VOL and the ultimate low voltage level VOL.

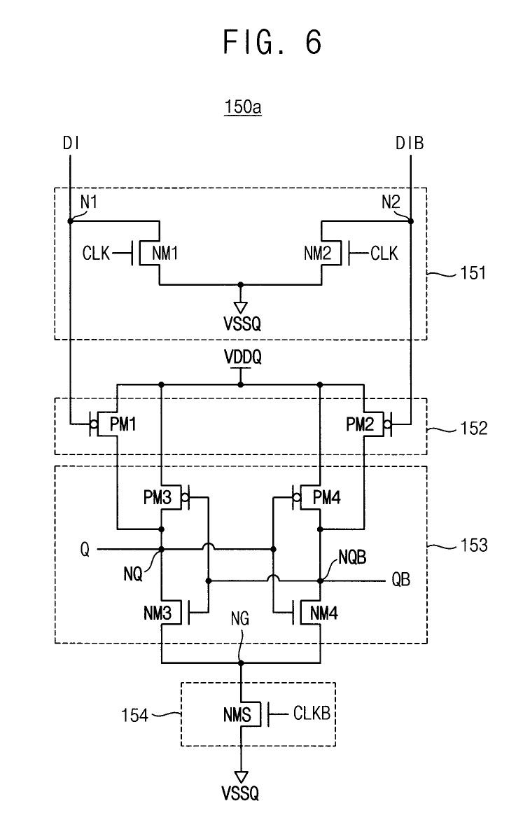

FIG. 6 is a circuit diagram illustrating an example of an amplifier in the receiver circuit of FIG. 1 according to example embodiments.

Referring to FIG. 6, an amplifier 150a may include a pull down circuit 151, a voltage-current conversion circuit 152, a latch circuit 153 and a switching circuit 154.

The latch circuit 153 is coupled between the power supply voltage VDDQ and a ground node NG. The latch circuit 153 includes a latch node NQ and an inversion latch node NQB generating the first output signal Q and the second output signal QB, respectively. The latch circuit 153 may be implemented with two inverters including two PMOS transistors PM3 and PM4 and two NMOS transistors NM3 and NM4, where the inputs and outputs of the inverters are cross-coupled.

The switching circuit 154 may include a switching NMOS transistor NMS. The switching NMOS transistor NMS applies the ground voltage VSSQ to the ground node NG in response to an inverted clock signal CLKB. The switching NMOS transistor NMS is turned off during the first half-cycle corresponding to logic low level of the inverted clock signal CLKB to float the ground node NG. The switching NMOS transistor NMS is turned on during the second half-cycle corresponding to logic high level of the inverted clock signal CLKB to apply the ground voltage VSSQ to the ground node NG. Accordingly the receiver circuit RX may repeat the sensing operation during the first half-cycle and the floating operation during the second half-cycle.

The pull down circuit 151 may include a first NMOS transistor NM1 and a second NMOS transistor NM2. The first NMOS transistor NM1 is coupled between the ground voltage VSSQ and the first node N1 receiving the first sensing signal DI and a gate of the first NMOS transistor NM1 receives the clock signal CLK. The second NMOS transistor NM2 is coupled between the ground voltage VSSQ and the second node N2 receiving the second sensing signal DIB and a gate of the second NMOS transistor NM2 receives the clock signal CLK.

The voltage-current conversion circuit 152 may include a first PMOS transistor PM1 and a second PMOS transistor PM2. The first PMOS transistor PM1 is coupled between the power supply voltage VDDQ and the latch node NQ, and a gate of the first PMOS transistor PM1 receives the first sensing signal DI. The second PMOS transistor PM2 is coupled between the power supply voltage VDDQ and the inversion latch node NQB, and a gate of the second PMOS transistor PM2 receives the second sensing signal DIB. The voltage-current conversion circuit 152 applies the currents corresponding to the first and second sensing signals DI and DIB to the latch node NQ and the inversion latch node NQB, respectively.

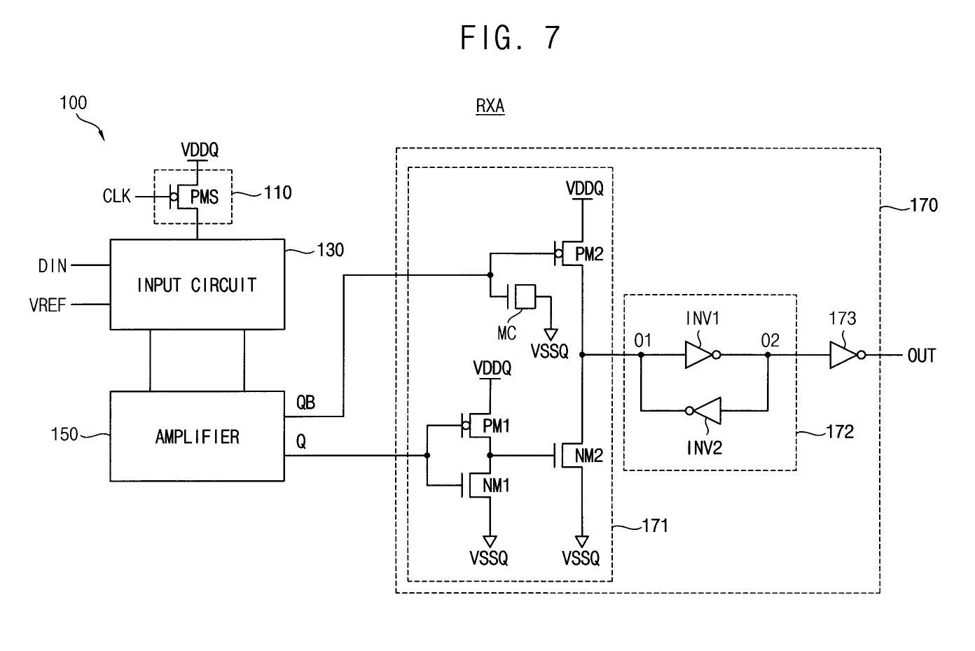

FIG. 7 is a diagram illustrating a receiver circuit RXA according to another example embodiments.

Referring to FIG. 7, a receiver circuit RXA may include a p-type sense amplifier 100 and a post-amplifier 170. The p-type sense amplifier 100 may include the switching circuit 110, the input circuit 130 and the amplifier 150 as described with reference to FIG. 1.

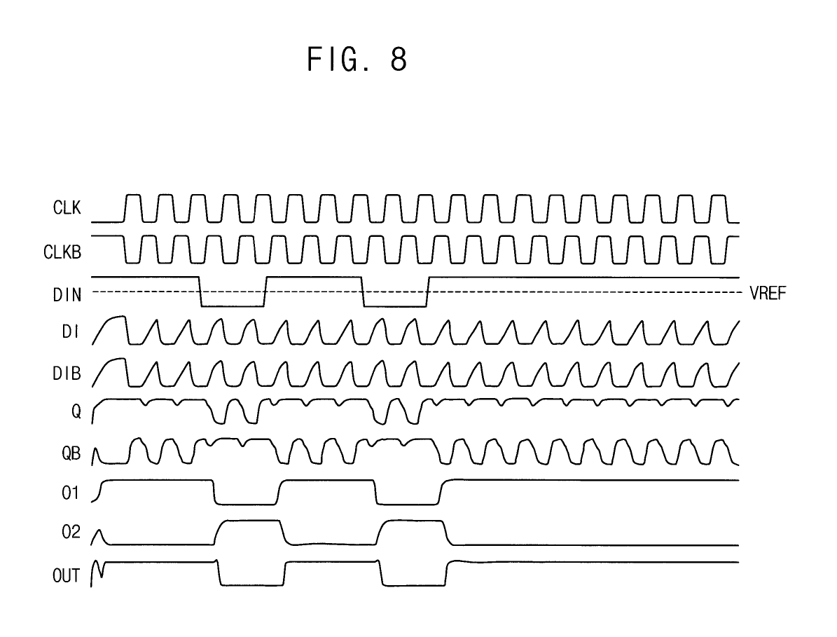

The post-amplifier 170 may amplify the first output signal Q and the second output signal QB to generate a third output signal OUT that swings fully between the power supply voltage VDDQ and the ground voltage VSSQ. As the frequency of the clock signal CLK is increased, the first and second output signals Q and QB may not swing fully as illustrated in FIG. 8. In this case, the post-amplifier 170 may further amplify the first and second output signals Q and QB to provide the third output signal OUT that swings fully between the power supply voltage VDDQ and the ground voltage VSSQ.

The post-amplifier 170 may include a driving circuit 171, a latch circuit 172 and an output circuit 173. The driving circuit 171 may include transistors NM1, NM2, PM1 and PM2 and a MOS capacitor MC that are coupled as illustrated in FIG. 7. The latch circuit 172 may include inverters INV1 and INV2 where inputs and outputs of the inverters INV1 and INV2 are cross-coupled. The node voltages O1 and O2 of the latch circuit 172 have complementary voltage levels. The output circuit 173 may be implemented with an inverter to output the third output signal OUT.

FIG. 8 is a diagram illustrating an example operation of a receiver circuit according to example embodiments.

Referring FIGS. 1, 6 and 8, the input circuit 130 of the p-type sense amplifier 100 generates the first sensing signal DI and the second sensing signal DIB based on the input signal DIN and the one reference voltage VREF. The p-type sense amplifier 100 may be floated during the first half-cycle corresponding to logic high level of the clock signal CLK and may perform the sensing operation during the second half-cycle corresponding to logic low level of the clock signal CLK. The first and second sensing signals DI and DIB may be provided as the voltage signals to the voltage-current conversion circuit 152 and voltage levels of the first and second output signals Q and QB may be formed by the output currents from the voltage-current conversion circuit 152. As described above, the first and second output signals Q and QB may not swing fully and the post-amplifier 170 may further amplify the first and second output signals Q and QB, through the node voltages O1 and O2, to provide the third output signal OUT that swings fully between the power supply voltage VDDQ and the ground voltage VSSQ.

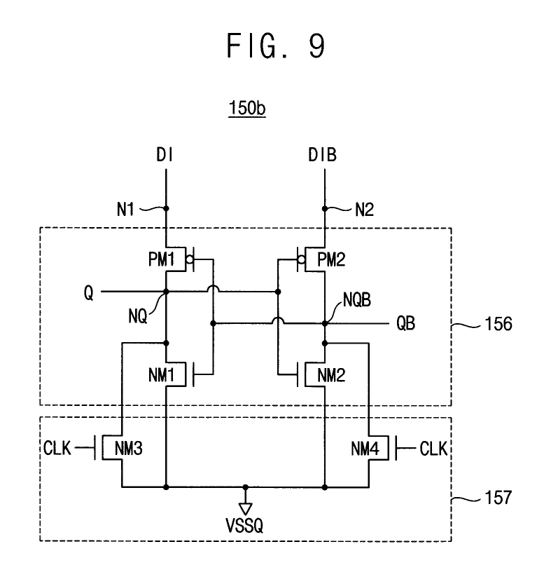

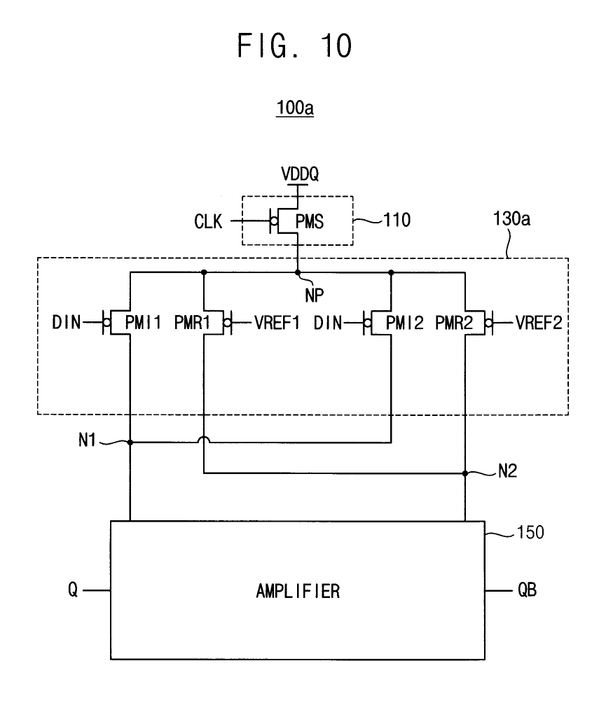

FIG. 9 is a circuit diagram illustrating another example of an amplifier in the receiver circuit of FIG. 1 according to example embodiments.

Referring to FIG. 9, an amplifier 150b may include a latch circuit 156 and a pull down circuit 157.

The latch circuit 156 is coupled between the first node N1 receiving the first sensing signal DI, the second node N2 receiving the second sensing signal DIB and the ground voltage VSSQ. The latch circuit 156 may include a latch node Q and an inversion latch node QB generating the first output signal Q and the second output signal QB, respectively. The latch circuit 153 includes a latch node NQ and an inversion latch node NQB generating the first output signal Q and the second output signal QB, respectively. The latch circuit 156 may be implemented with two inverters including two PMOS transistors PM1 and PM2 and two NMOS transistors NM1 and NM2, where the inputs and outputs of the inverters are cross-coupled.

The pull down circuit 157 may include a first NMOS transistor NM3 and a second NMOS transistor NM4. The first NMOS transistor NM3 is coupled between the ground voltage VSSQ and the latch node Q, and a gate of the first NMOS transistor NM3 receives the clock signal CLK. The second NMOS transistor NM4 is coupled between the ground voltage VSSQ and the inversion latch node QB, and a gate of the second NMOS transistor NM4 receives the clock signal CLK.

FIG. 10 is a diagram illustrating a receiver circuit according to another example embodiments.

Referring to FIG. 10, a p-type sense amplifier 100a may include a switching circuit 110, an input circuit 130a and an amplifier 150. The switching circuit 110 may include a switching PMOS transistor PMS. The switching PMOS transistor PMS applies a power supply voltage VDDQ to a power node NP in response to a clock signal CLK. The switching PMOS transistor PMS is turned off during a first half-cycle corresponding to logic high level of the clock signal CLK to float the power node NP. The switching PMOS transistor PMS is turned on during a second half-cycle corresponding to logic low level of the clock signal CLK to apply the power supply voltage VDDQ to the power node NP. Accordingly the p-type sense amplifier 100a may repeat the sensing operation during the first half-cycle and the floating operation during the second half-cycle.

The input circuit 130a is coupled to the power node NP to receive a power. The input circuit 130a includes a plurality of PMOS transistors PMI1, PMR1, PMI2 and PMR2 that generate a first sensing signal DI and a second sensing signal DIB in response to an input signal DIN and a plurality of reference voltages VREF1 and VREF2, such that the first sensing signal DI corresponds to the input signal DIN and the second sensing signal DIB corresponds to the reference voltages VREF1 and VREF2.

The amplifier 150 amplifies the first sensing signal DI and the second sensing signal DIB to generate a first output signal Q and a second output signal QB.

As described above, a ground termination circuit may be coupled between a ground voltage VSSQ and a reception node NR receiving the input signal DIN. In this case, the input signal DIN swings between the low voltage level VOL and the high voltage level VOH, as described with reference to FIG. 5. The low voltage level VOL may correspond to the ground voltage VSSQ (e.g., 0 V) and the high voltage level VOH may be lower than the power supply voltage VDDQ.

In case that the two reference voltages VREF1 and VREF2 are used, the input circuit 130a may include a first input PMOS transistor PMI1, a first reference PMOS transistor PMR1, a second input PMOS transistor PMI2 and a second reference PMOS transistor PMR2.

The first input PMOS transistor PMI1 is coupled between the power node NP and a first node N1 generating the first sensing signal DI, and a gate of the first input PMOS transistor PMI1 receives the input signal DIN. The first reference PMOS transistor PMR1 is coupled between the power node NP and a second node N2 generating the second sensing signal DIB, and a gate of the first reference PMOS transistor PMR1 receives the first reference voltage VREF1. The second input PMOS transistor PMI2 is coupled between the power node NP and the first node N1, and a gate of the second input PMOS transistor PMI2 receives the input signal DIN. The second reference PMOS transistor PMR2 is coupled between the power node NP and the second node N2, and a gate of the second reference PMOS transistor PMR2 receives the second reference voltage VREF2.

For example, the first reference voltage VREF1 has a voltage level higher than an average voltage level VA of the low voltage level VOL and the high voltage level VOH of the input signal DIN, and the second reference voltage VREF2 has a voltage level lower than the average voltage level VA. In one example embodiment, the first reference voltage VREF1 may have the high voltage level VOH of the input signal DIN, and the second reference voltage VREF2 may have the low voltage level VOL of the input signal DIN.

FIG. 10 illustrates a non-limiting example embodiment that the two reference voltages VREF1 and VREF2 are used to sensing the input signal DIN, and three or more reference voltages may be used. For example, the at least one reference voltage may include three voltages as the first reference voltage VREF1, the second reference voltage VREF2 and the reference voltage VREF having the average voltage level VA. In this case, the input circuit may include three input PMOS transistors coupled in parallel between the power node NP and the first node N1 and commonly receiving the input signal DIN, and three reference PMOS transistors coupled in parallel between the power node NP and the second node N2 and respectively receiving the three reference voltages VREF1, VREF2 and VREF. As such, the input signal DIN may be sensed using four reference voltages including two voltages higher than the average voltage level VA and two voltages lower than the average voltage level VA.

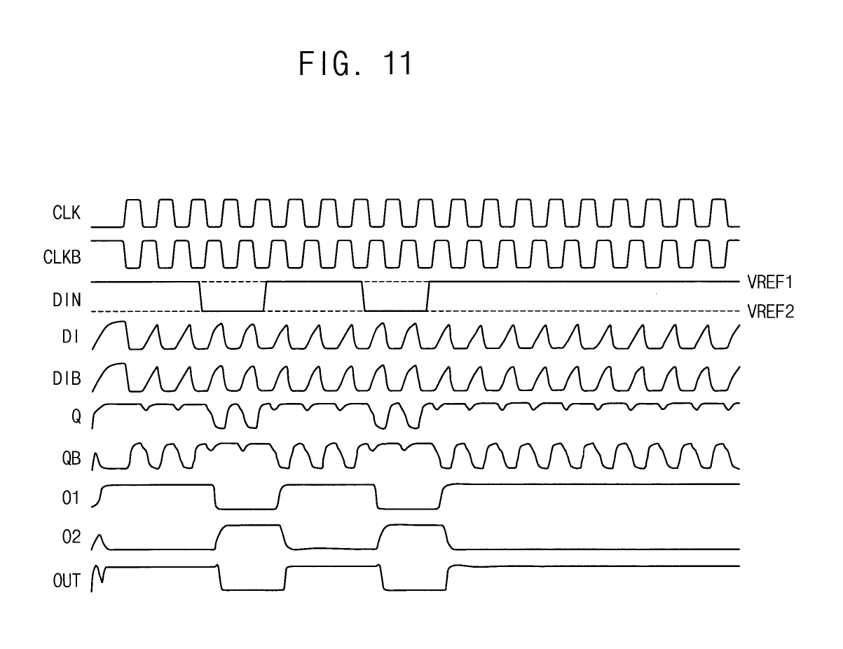

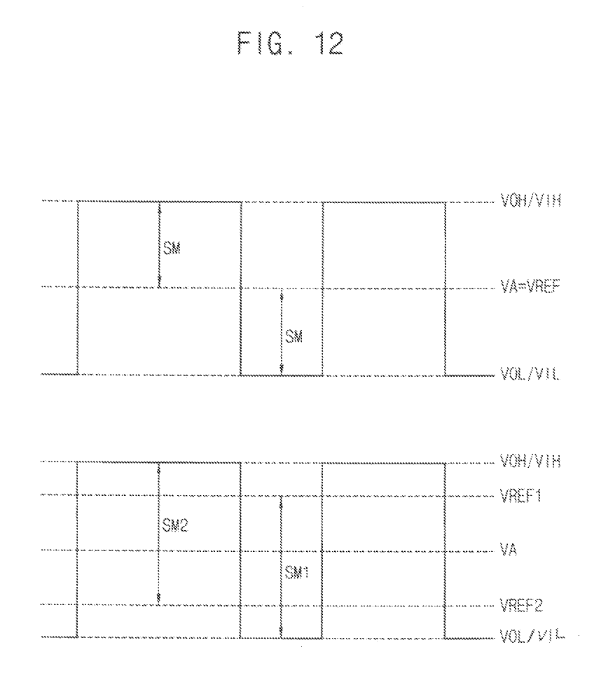

FIG. 11 is a diagram illustrating an example operation of a receiver circuit according to example embodiments.

Referring FIGS. 6, 10 and 11, the input circuit 130a of the p-type sense amplifier 100a generates the first sensing signal DI and the second sensing signal DIB based on the input signal DIN and the two reference voltages VREF1 and VREF2.

For example, the first reference voltage VREF1 may have the high voltage level VOH of the input signal DIN and the second reference voltage VREF2 may have the low voltage level VOL of the input signal DIN, as illustrated in FIG. 11.

In this case, when the input signal DIN has the low voltage level VOL, the current passing through the second input PMOS transistor PMI2 is equal to the current passing through the second reference PMOS transistor PMR2 because the voltage levels of the input signal DIN and the second reference voltage VREF2 are the same. As a result, the input circuit 130a may generate the first sensing signal DI and the second sensing signal DIB based on the input signal DIN applied to the first input PMOS transistor PMI1 and the first reference voltage VREF1 applied to the first reference PMOS transistor PMR1, when the input signal DIN has the low voltage level VOL.

When the input signal DIN has the high voltage level VOH, the current passing through the first input PMOS transistor PMI1 is equal to the current passing through the first reference PMOS transistor PMR1 because the voltage levels of the input signal DIN and the first reference voltage VREF1 are the same. As a result, the input circuit 130a may generate the first sensing signal DI and the second sensing signal DIB based on the input signal DIN applied to the second input PMOS transistor PMI2 and the second reference voltage VREF2 applied to the second reference PMOS transistor PMR2, when the input signal DIN has the low high level VOH.

The p-type sense amplifier 100a may be floated during the first half-cycle corresponding to logic high level of the clock signal CLK and may perform the sensing operation during the second half-cycle corresponding to logic low level of the clock signal CLK. The first and second sensing signals DI and DIB may be provided as the voltage signals to the voltage-current conversion circuit 152 and voltage levels of the first and second output signals Q and QB may be formed by the output currents from the voltage-current conversion circuit 152. As described above, the first and second output signals Q and QB may not swing fully between the power supply voltage VDDQ and the ground voltage VSSQ, and the post-amplifier 170 may further amplify the first and second output signals Q and QB, through the node voltages O1 and O2, to provide the third output signal OUT that swings fully between the power supply voltage VDDQ and the ground voltage VSSQ.

FIG. 12 is a diagram illustrating sensing margins of receiver circuits according to example embodiments.

A sensing margin SM, when the one reference voltage VREF having the average voltage level VA of the high voltage level VOH and the low voltage level VOL of the input signal is used to sensing the input signal, is illustrated in the upper portion of FIG. 12. In this case, the sensing margin SM is equal to the average voltage level VA with respect to both cases that the input signal has the high voltage level VOH and the low voltage level VOL.

Sensing margins SM1 and SM2, when the first reference voltage VREF1 having the high voltage level VOH higher than the average voltage level VA and the second reference voltage VREF2 having the low voltage level VOL lower than the average voltage level VA are used to sensing the input signal, are illustrated in the bottom portion of FIG. 12. In this case, the first sensing margin SM1 is secured when the input signal has the low voltage level VOL because the first reference voltage VREF1 is compared with the low voltage level VOL of the input signal, and the second sensing margin SM2 is secured when the input signal has the high voltage level VOH because the second reference voltage VREF2 is compared with the high voltage level VOH of the input signal. Both of the first and second sensing margins SM1 and SM2 are greater than the average voltage level VA. As such, by increasing the sensing margins using the plurality of the reference voltages, sensitivity to the input signal may be further enhanced.

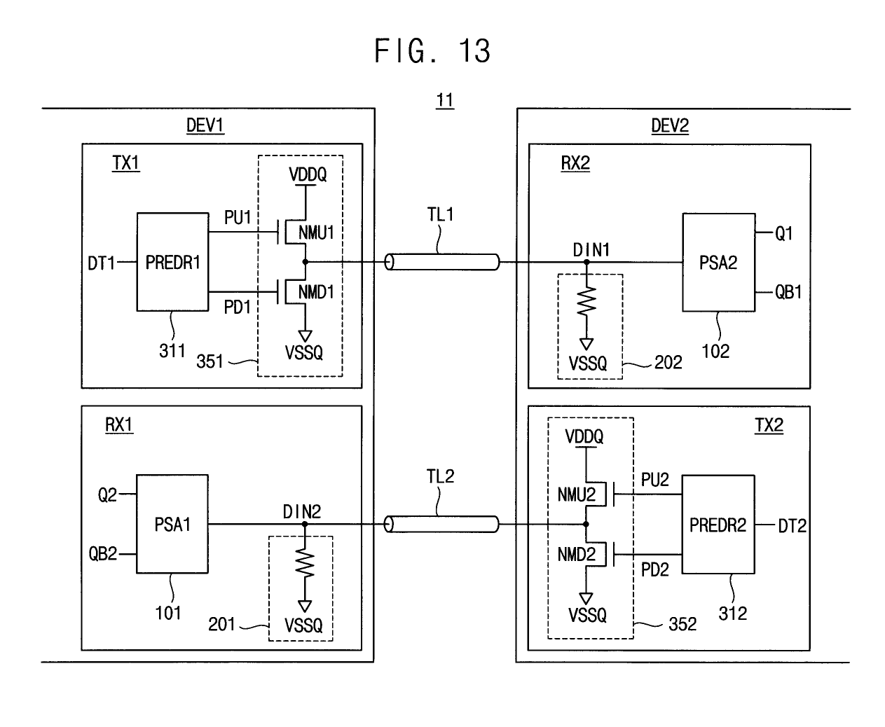

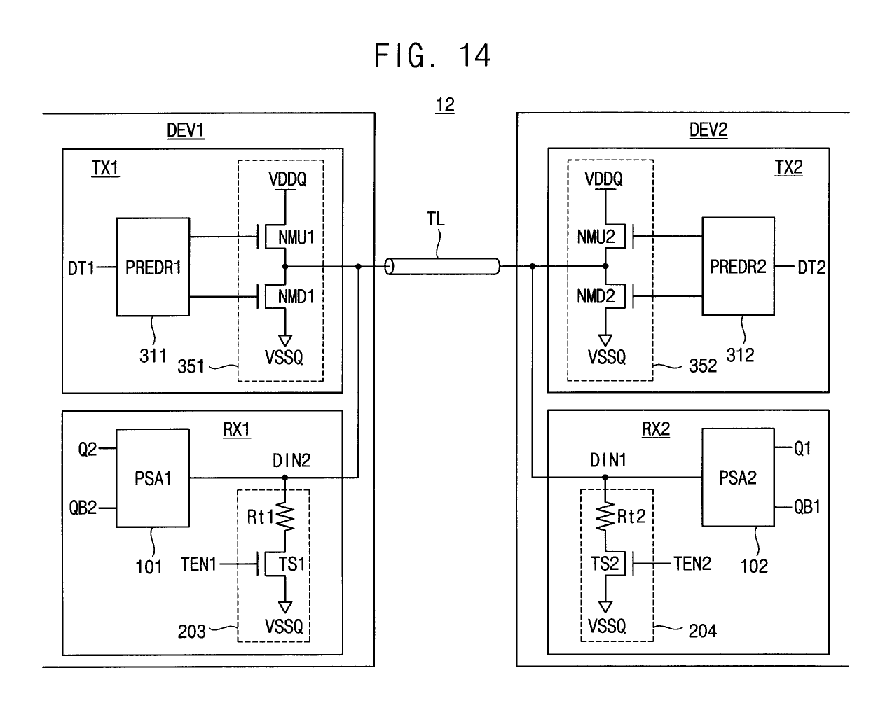

FIGS. 13 and 14 are diagrams illustrating systems of performing bi-directional communication according to example embodiments.

FIG. 13 illustrates an example configuration for performing bi-directional communication using two uni-lateral transmission lines TL1 and TL2, and FIG. 14 illustrates another example configuration for performing bi-directional communication using one bi-lateral transmission line TL.

Referring to FIG. 13, a system 11 includes a first device DEV1 and a second device DEV2 coupled through the two transmission lines TL1 and TL2. The first device DEV1 includes a first transmitter circuit TX1 and a first receiver circuit RX1, and the second device DEV2 includes a second transmitter circuit TX2 and a second receiver circuit RX2. The transmitter circuits TX1 and TX2 may include pre-drivers 311 and 312 and transmission drivers 351 and 352, respectively. The receiver circuits RX1 and RX2 may include ground termination circuits 201 and 202 and p-type sense amplifiers 101 and 102, respectively. The transmission drivers 351 and 352 may include pull up NMOS transistors NMU1 and NMU2 and pull down NMOS transistors NMD1 and NMD2 coupled between the power supply voltage VDDQ and the ground voltage VSSQ, respectively. The p-type sense amplifiers 101 and 102 may include the switching circuits, the input circuits and the amplifiers, respectively, as described with reference to FIGS. 1 through 12.

The first pre-driver 311 in the first device DEV1 outputs a pull up signal PU1 and a pull down signal PD1 corresponding to a first transmission signal DT1, and the first transmission driver 351 in the first device DEV1 drives the first transmission line TL1 in response to the pull up signal PU1 and the pull down signal PD1. The second p-type sense amplifier 102 in the second device DEV2 senses a first input signal DIN1 transferred through the first transmission line TL1 to generate output signals Q1 and QB1.

The second pre-driver 312 in the second device DEV2 outputs a pull up signal PU2 and a pull down signal PD2 corresponding to a second transmission signal DT2, and the second transmission driver 352 in the second device DEV2 drives the second transmission line TL2 in response to the pull up signal PU2 and the pull down signal PD2. The first p-type sense amplifier 101 in the first device DEV2 senses a second input signal DIN2 transferred through the second transmission line TL2 to generate output signals Q2 and QB2.

As such, the system 11 may perform bi-lateral communication using the two uni-lateral transmission lines TL1 and TL2. For example, the NMOS transistors NMU1 and NMU2 may be used as pull up drivers to increase the integration rate and the operational speed of the circuits, and the p-type sense amplifiers 101 and 102 may be used to efficiently receive the input signals DIN1 and DIN2 that swing narrowly near the ground voltage VSSQ (e.g., under 1V).

Referring to FIG. 14, a system 12 includes a first device DEV1 and a second device DEV2 coupled through the one transmission line TL. The first device DEV1 includes a first transmitter circuit TX1 and a first receiver circuit RX1, and the second device DEV2 includes a second transmitter circuit TX2 and a second receiver circuit RX2. The transmitter circuits TX1 and TX2 may include pre-drivers 311 and 312 and transmission drivers 351 and 352, respectively. The receiver circuits RX1 and RX2 may include ground termination circuits 203 and 204 and p-type sense amplifiers 101 and 102, respectively. The transmission drivers 351 and 352 may include pull up NMOS transistors NMU1 and NMU2 and pull down NMOS transistors NMD1 and NMD2 coupled between the power supply voltage VDDQ and the ground voltage VSSQ, respectively. The p-type sense amplifiers 101 and 102 may include the switching circuits, the input circuits and the amplifiers, respectively, as described with reference to FIGS. 1 through 12.

Compared with the ground termination circuits 201 and 202 in FIG. 13, the ground termination circuits 203 and 204 may further include switches TS1 and TS2 coupled between the ground voltage VSSQ and the termination resistors Rt1 and Rt2, respectively. The first switch TS1 may be turned on in response to a first termination enable signal TEN1 and the second switch TS2 may be turned on in response to a second termination enable signal TEN2, where the first and second termination signals TEN1 and TEN2 are activated complementarily.

The first pre-driver 311 in the first device DEV1 outputs a pull up signal PU1 and a pull down signal PD1 corresponding to a first transmission signal DT1, and the first transmission driver 351 in the first device DEV1 drives the first transmission line TL1 in response to the pull up signal PU1 and the pull down signal PD1. The second p-type sense amplifier 102 in the second device DEV2 senses a first input signal DIN1 transferred through the first transmission line TL1 to generate output signals Q1 and QB1.

The second pre-driver 312 in the second device DEV2 outputs a pull up signal PU2 and a pull down signal PD2 corresponding to a second transmission signal DT2, and the second transmission driver 352 in the second device DEV2 drives the second transmission line TL2 in response to the pull up signal PU2 and the pull down signal PD2. The first p-type sense amplifier 101 in the first device DEV2 senses a second input signal DIN2 transferred through the second transmission line TL2 to generate output signals Q2 and QB2.

When the signal is transferred from the first device DEV1 to the second device DEV2, the first transmitter circuit TX1 and the second receiver circuit RX2 are enabled and the second transmitter circuit TX2 and the first receiver circuit RX1 are disabled. In this case, the first ground termination circuit 203 is disabled in response to the deactivated first termination enable signal TEN1 and the second ground termination circuit 204 is enabled in response to the activated second termination enable signal TEN2.

When the signal is transferred from the second device DEV2 to the first device DEV1, the second transmitter circuit TX2 and the first receiver circuit RX1 are enabled and the first transmitter circuit TX1 and the second receiver circuit RX2 are disabled. In this case, the second ground termination circuit 204 is disabled in response to the deactivated second termination enable signal TEN2 and the first ground termination circuit 203 is enabled in response to the activated first termination enable signal TEN1.

As such, the system 12 may perform bi-lateral communication using the one bi-lateral transmission line TL. According to example embodiments, the NMOS transistors NMU1 and NMU2 may be used as pull up drivers to increase the integration rate and the operational speed of the circuits, and the p-type sense amplifiers 101 and 102 may be used to efficiently receive the input signals DIN1 and DIN2 that swing narrowly near the ground voltage VSSQ.

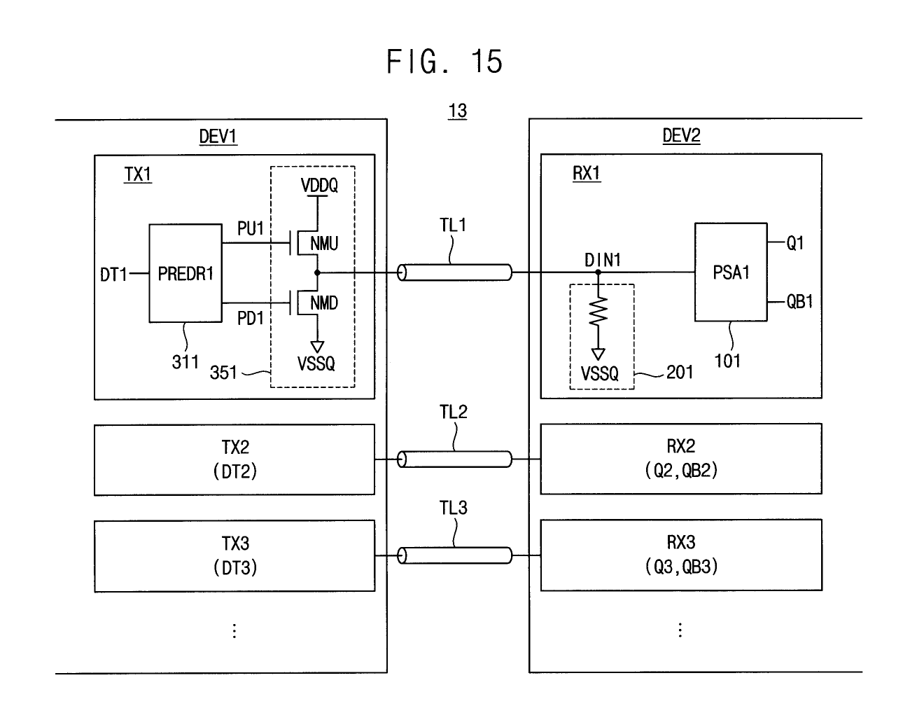

FIG. 15 is a diagram illustrating a multi-channel system according to example embodiments.

Referring to FIG. 15, a system 13 includes a first device DEV1 and a second device DEV2 coupled through a plurality of transmission lines TL1, TL2 and TL3. The first device DEV1 includes a plurality of transmitter circuits TX1, TX2 and TX3 and the second device DEV2 includes a plurality of receiver circuits RX1, RX2 and RX3. The transmitter circuits TX1, TX2 and TX3 may have the same configuration and receiver circuits RX1, RX2 and RX3 may have the same configuration. For example, the first transmitter circuit TX1 may include a pre-driver 311 and a transmission driver 351, and the first receiver circuit RX1 may include a ground termination circuit 201 and a p-type sense amplifier 101. The transmission driver 351 may include a pull up NMOS transistor NMU and a pull down NMOS transistor NMD coupled between the power supply voltage VDDQ and the ground voltage VSSQ. The p-type sense amplifier 101 may include the switching circuit, the input circuit and the amplifier as described with reference to FIGS. 1 through 12.

The pre-driver 311 in the first transmitter circuit TX1 outputs a pull up signal PU1 and a pull down signal PD1 corresponding to a first transmission signal DT1, and the first transmission driver 351 in the first transmitter circuit TX1 drives the first transmission line TL1 in response to the pull up signal PU1 and the pull down signal PD1. The p-type sense amplifier 101 in the first receiver circuit RX1 senses a first input signal DIN1 transferred through the first transmission line TL1 to generate output signals Q1 and QB1. In the same way, the second transmitter circuit TX2 drives the second transmission line TL2 based on a second transmission signal DT2 and the second receiver circuit RX2 receives a second input signal DIN2 through the second transmission line TL2 to generate output signals Q2 and QB2. The third transmitter circuit TX3 drives the third transmission line TL3 based on a third transmission signal DT3 and the third receiver circuit RX3 receives a third input signal DIN3 through the third transmission line TL3 to generate output signals Q3 and QB3.

FIGS. 13 and 14 illustrate the bi-lateral communication systems 11 and 12, and FIG. 15 illustrates uni-lateral multi-channel system 13. As the combination of the bi-lateral communication system 11 or 12 and the multi-channel system 13, a bi-lateral multi-channel system may be implemented.

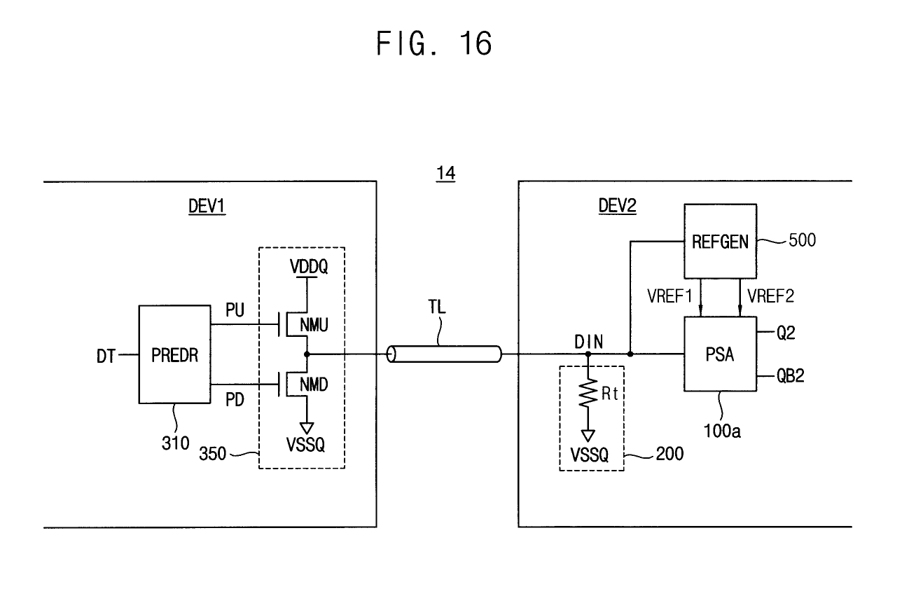

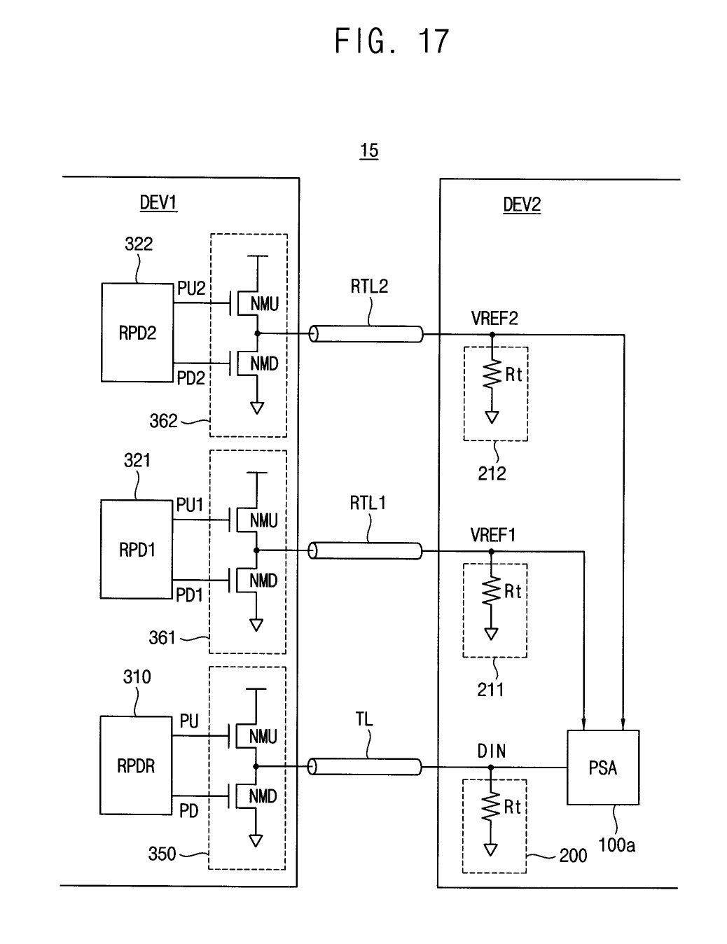

FIGS. 16 and 17 are diagrams illustrating systems of providing reference voltages according to example embodiments.

Referring to FIG. 16, a system 14 includes a first device DEV1 and a second device DEV2 coupled through a transmission line TL. The first device DEV1 may include a pre-driver 310 and a transmission driver 350 as described above to operate as a transmitter. The second device DEV2 may include a p-type sense amplifier 100a and a ground termination circuit 200 as described above to operate as a receiver.

As illustrated in FIG. 16, the second device DEV2 operating as the receiver may further include a reference voltage generator (REFGEN) 500. The reference voltage generator 500 may generate a first reference voltage VREF1 and a second reference voltage VREF2 based on at least one input signal DIN. The first reference voltage VREF1 may have a voltage level higher than an average voltage level VA between the low voltage level VOL and the high voltage level VOH of the input signal DIN, and the second reference voltage VREF2 may have a voltage level lower than the average voltage level VA. For example, the reference voltage generator 500 may measure the low voltage level VOL and the high voltage level VOH of the input signal DIN during the initializing operation of the system 14 and may determine the voltage levels of the first and second reference voltages VREF1 and VREF2 based on the measured values.

The p-type sense amplifier 100a may have the configuration as illustrated in FIG. 10 and may increase the sensing margins using the first and second reference voltages VREF1 and VREF2 to enhance the sensitivity to the input signal DIN.

Referring to FIG. 17, a system 15 includes a first device DEV1 and a second device DEV2 coupled through transmission lines TL, RTL1 and RTL2. The first device DEV1 may include a pre-driver 310 and a transmission driver 350 as described above to operate as a transmitter. The second device DEV2 may include a p-type sense amplifier 100a and a ground termination circuit 200 as described above to operate as a receiver.

As illustrated in FIG. 17, the first device DEV1 operating as the transmitter may further include a first reference driver 361 and a second reference driver 362. The first reference driver 362 may have substantially same configuration as the transmission driver 350 to provide a first reference voltage VREF1 to the second device operating as the receiver. The first reference voltage VREF1 may have the high voltage level VOH of the input signal DIN. The second reference driver 362 may have substantially same configuration as the transmission driver 350 to provide a second reference voltage VREF2 to the second device DEV2 operating as the receiver. The second reference voltage VREF2 may have the low voltage level VOL of the input signal DIN. The first reference voltage VREF1 and the second reference voltage VREF2 may be transferred to the second device DEV2 through the reference voltage transmission lines RTL1 and RTL2, respectively. The reference voltage transmission lines RTL1 and RTL2 may be terminated by the ground termination circuits 211 and 212 that have the same configuration as the ground termination circuit 200 of the signal transmission line TL. The first device DEV1 may further include reference pre-drivers 321 and 322 configured to provide the control signals PU1, PD1, PU2 and PU2 to the reference drivers 361 and 362.

The first device DEV1 may be formed through the common manufacturing process and may be integrated in one chip. In this case, the elements 321, 322, 361 and 362 for providing the reference voltages VREF1 and VREF2 may have the same operational characteristics as the elements 310 and 350 for transferring the signal. Accordingly the reference voltages VREF1 and VREF2 may reflect exactly the high voltage level VOH and the low voltage level VOL of the input signal DIN because the variations due to the manufacturing process, the operational voltage and the operational temperature are applied commonly to the reference voltage transfer and the signal transfer.

The p-type sense amplifier 100a may have the configuration as illustrated in FIG. 10 and may increase the sensing margins using the first and second reference voltages VREF1 and VREF2 to enhance the sensitivity to the input signal DIN.

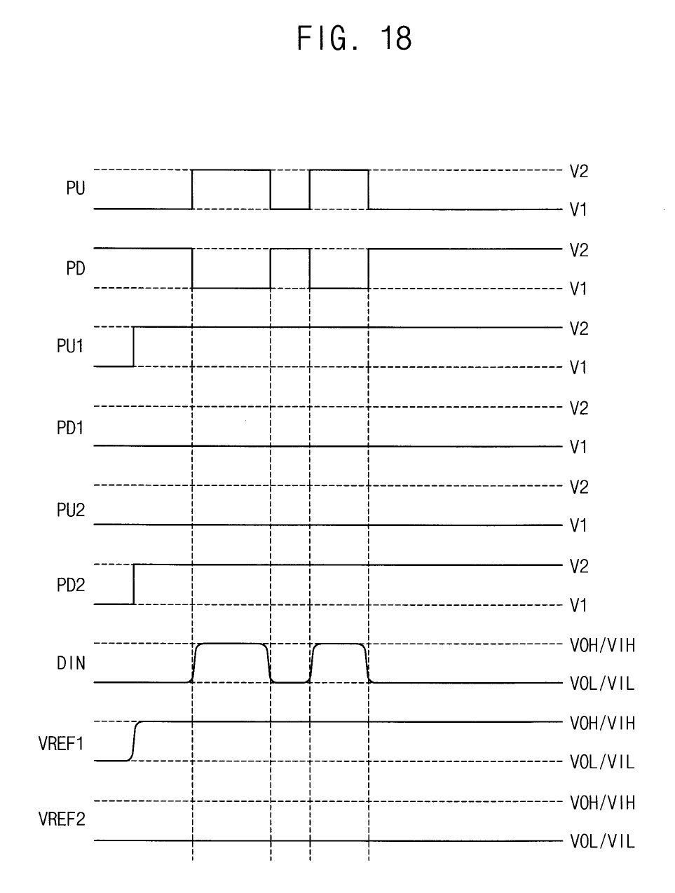

FIG. 18 is a diagram illustrating an operation of the system of FIG. 17 according to example embodiments.

Referring to FIG. 18, the pull up signal PU and the pull down signal PD from the pre-driver 310 transition complementarily between a first voltage V1 and a second voltage V2, depending on the transmission signal. The first voltage V1 may be a power supply voltage of the first device DEV1 and the second voltage V2 may be a ground voltage of the first device DEV1.

The first reference pre-driver 321 may be configured to output the pull up signal PU1 fixed at the first voltage V1 and the pull down signal PD1 fixed at the second voltage V2. In this case, the pull up NMOS transistor NMU of the first reference driver 361 may be always turned on and the pull down NMOS transistor NMD of the first reference driver 361 may be always turned off. As a result, the first reference voltage VREF1 received by the second device DEV2 through the first reference voltage transmission line RTL1 may have the high voltage level VOH of the input signal DIN.

The second reference pre-driver 322 may be configured to output the pull up signal PU2 fixed at the second voltage V2 and the pull down signal PD2 fixed at the first voltage V1. In this case, the pull up NMOS transistor NMU of the second reference driver 362 may be always turned off and the pull down NMOS transistor NMD of the second reference driver 362 may be always turned on. As a result, the second reference voltage VREF2 received by the second device DEV2 through the second reference voltage transmission line RTL2 may have the low voltage level VOL of the input signal DIN.

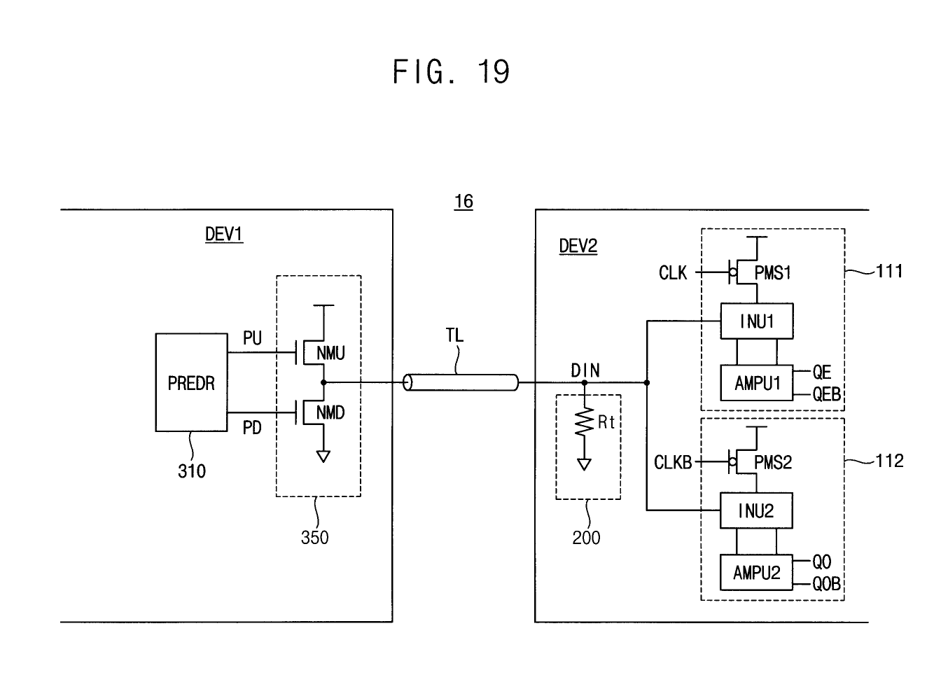

FIG. 19 is a diagram illustrating a system of performing a double data rate (DDR) transfer according to example embodiments.

Referring to FIG. 19, a system 16 includes a first device DEV1 and a second device DEV2 coupled through transmission line TL. The first device DEV1 may include a pre-driver 310 and a transmission driver 350 as described above to operate as a transmitter. The second device DEV2 may include a first p-type sense amplifier 111 and a second p-type sense amplifier 112 and a ground termination circuit 200 as described above to operate as a receiver.

The system 16 may perform the DDR transfer such that two bits may be transferred in a single cycle of the clock signal CLK. The first device DEV1 operating as the transmitter may have the configuration to perform the DDR transfer. For example, the pre-driver 310 may generate the pull up signal PD and the pull down signal PD such that one even-numbered bit and one odd-numbered bit in the transmission signal may be transferred in the single cycle of the clock signal CLK.

The clock signal CLK is applied to the gate of the switching PMOS transistor PMS1 in the first p-type sense amplifier 111, and the inverted clock signal CLKB is applied to the gate of the switching PMOS transistor PMS2 in the second p-type sense amplifier 112. The second p-type sense amplifier 112 may perform the sensing operation during the first half-cycle corresponding to the logic high level of the clock signal CLK and may be floated from the power supply voltage during the second half-cycle corresponding to the logic low level of the clock signal CLK. In contrast, the first p-type sense amplifier 111 may perform the sensing operation during the second half-cycle corresponding to the logic low level of the clock signal CLK and may be floated from the power supply voltage during the first half-cycle corresponding to the logic low high of the clock signal CLK. As a result, the first p-type sense amplifier 111 may sense the even-numbered bits in the input signal DIN to generate the even-numbered output signals QE and QEB and the second p-type sense amplifier 112 may sense the odd-numbered bits in the input signal DIN to generate the odd-numbered output signals QO and QOB.

As such, the frequency of the clock signal CLK may be increased by supporting the DDR transfer using the two p-type sense amplifiers 111 and 112 that operate complementarily, and the operational speed of the system 16 may be increased.

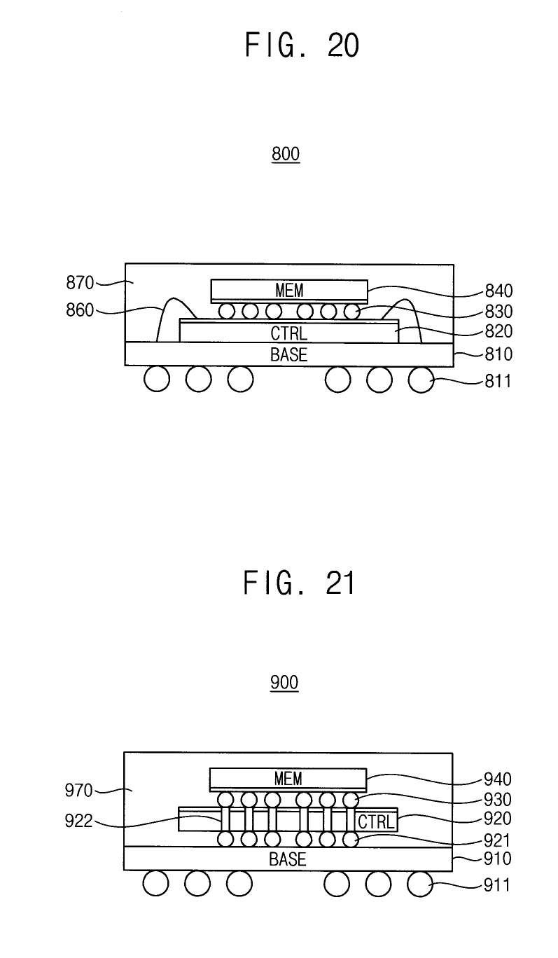

The devices of the embodiments described herein (e.g., DEV1 and DEV2) may each be formed as a single semiconductor chip, with the p-type sense amplifiers of the receivers RX of the devices connected to respective external transmission lines via terminals of the semiconductor chip (e.g., chip pads). Alternatively, devices described herein may be formed from multiple chips. For example, one or more of the devices DEV1 and DEV2 may be formed of multiple chips within a semiconductor package (e.g., stacked chips in a multi-chip package) with external terminals (e.g., solder bumps) of the semiconductor package connecting the p-type sense amplifiers to external transmission lines. FIGS. 20 and 21 illustrate semiconductor packages according to example embodiments. In these embodiments, the devices described herein may equate to packages 800/900 each with the p-type sense amplifiers of the receivers RX formed within controllers CTRL 820/920, having a data input DIN connection via a terminal of the package 800/900 (which may be electrically connected to a terminal of the controller CTRL 820/920). The controllers 820/920 and memory devices 840/940 may each be a semiconductor chip. Alternatively, a devices described herein may separately correspond to one of the controller CTRL 820/920 and/or memory devices 840/940, with the p-type sense amplifiers of the receiver RX formed in one or both of the controller CTRL 820/920 and memory devices 840/940. The data input DIN of the receiver RX may connect to a transmission line within the semiconductor package 800/900 connecting the controller CTRL 820/920 to the corresponding memory device 840/940.

Referring to FIG. 20, a semiconductor package 800 includes a base substrate (BASE) 810, a controller chip (CTRL) 820 disposed on the base substrate 810, and at least one semiconductor memory chip (MEM) 840 disposed on the controller chip 820. The base substrate 810 may be a printed circuit board (PCB), and the controller chip 820 may include a microprocessor unit (MPU). After the substrate 810 and the chips 820 and 840 are stacked, the upper portion of the semiconductor package 800 may be covered with resin 870. The semiconductor memory chip 840 and the controller chip 820 may perform the signal transfer according to example embodiments as described with reference to FIGS. 1 through 20.

For example, the semiconductor memory chip 840 and the controller chip 820 may be electrically connected to each other through the input-output bumps 830 the controller chip 820 and the base substrate 810 may be electrically connected to each other using wires 860. Bumps 811 for electrical connection to an external device may be formed under the bottom surface of the base substrate 810.

Referring to FIG. 21, a semiconductor package 900 includes a base substrate (BASE) 910, a controller chip (CTRL) 920 disposed on the base substrate 910, and at least one semiconductor memory chip (MEM) 940 disposed on the controller chip 920. The base substrate 910 may be a printed circuit board (PCB), and the controller chip 920 may include a microprocessor unit (MPU). After the substrate 910 and the chips 920 and 940 are stacked, the upper portion of the semiconductor package 900 may be covered with resin 970. The semiconductor memory chip 940 and the controller chip 920 may perform the signal transfer according to example embodiments as described with reference to FIGS. 1 through 20.

In the embodiment of FIG. 21, the semiconductor memory chip 940 and the controller chip 920 may be electrically connected to each other through the input-output bumps 930 that are formed on the semiconductor memory chip 940, and the controller chip 920 and the base substrate 810 may be electrically connected to each other using bumps 921 that are formed under the bottom surface of the controller chip 920. The controller chip 920 may include through-silicon vias (or, through-substrate vias) 922 to reduce interfacing resistance between the base substrate 910 and the controller chip 920. Bumps 911 for electrical connection to an external device may be formed under the bottom surface of the base substrate 910.

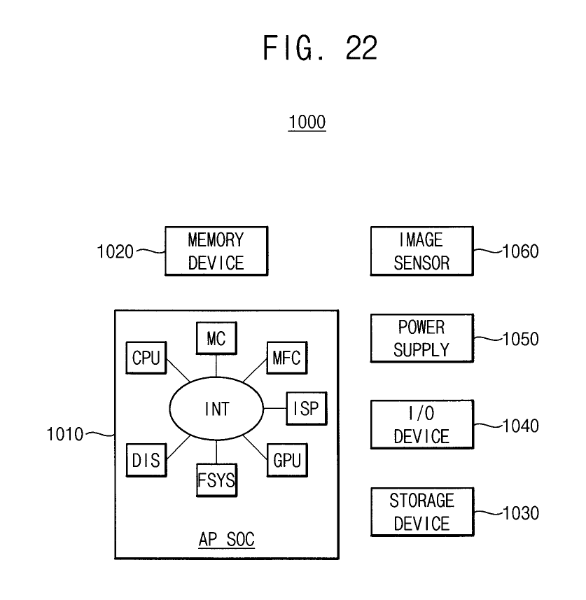

FIG. 22 is a block diagram illustrating an electronic device according to example embodiments. Portions of the electronic device 1000 may correspond to the devices (e.g., DEV1 and/or DEV2) described herein.

Referring to FIG. 22, an electronic device 1000 may include a system on chip (SOC) 1010, a memory device 1020, a storage device 1030, an input/output (I/O) device 1040, a power supply 1050 and an image sensor 1060. Although it is not illustrated in FIG. 22, the electronic device 1000 may further include ports that communicate with a video card, a sound card, a memory card, a USB device, or other electronic devices.

The SOC 1010 may be an application processor (AP) SOC including an interconnect device INT and a plurality of intellectual properties or functional blocks coupled to the interconnect device INT. For example, the intellectual properties may include a memory controller MC, a central processing unit CPU, a display controller DIS, a file system block FSYS, a graphic processing unit GPU, an image signal processor ISP, a multi-format codec block MFC, etc.

The memory controller MC and the memory device 1020 may perform the signal transfer according to example embodiments as described with reference to FIGS. 1 through 20.

The SOC 1010 may communicate with the memory device 1020, the storage device 1030, the input/output device 1040 and the image sensor 1060 via a bus such as an address bus, a control bus, and/or a data bus. In some embodiments, the SOC 1010 may be coupled to an extended bus, such as a peripheral component interconnection (PCI) bus. Devices described herein with respect to other embodiments (e.g., DEV1 and DEV2) may correspond to one or more of the memory device 1020, the storage device 1030, the input/output device 1040 and the image sensor 1060. One or more receivers RX of the embodiments described herein may be formed in one or more of the memory device 1020, the storage device 1030, the input/output device 1040 and the image sensor 1060. One or more transmitters TX of the embodiments described herein may be formed in one or more of the memory device 1020, the storage device 1030, the input/output device 1040 and the image sensor 1060. Transmission lines may connect such receivers RX and transmitters TX. Alternatively, the devices described herein (e.g., DEV1 and DEV2) may correspond to one or more of the functional blocks of the SOC 1010. Transmission lines connecting respective receivers RX and transmitters TX may be thus formed as part of chip SOC 1010, or on-chip to the SOC 1010. The details of such connections and respective operations have been previously described and need not be repeated here.

The memory device 1020 may store data for operating the computing system 2000. For example, as with memory devices of other embodiments described herein, the memory device 1020 may be implemented with a dynamic random access memory (DRAM) device, a mobile DRAM device, a static random access memory (SRAM) device, a phase random access memory (PRAM) device, a ferroelectric random access memory (FRAM) device, a resistive random access memory (RRAM) device, and/or a magnetic random access memory (MRAM) device. The storage device 1030 may include a solid state drive (SSD), a hard disk drive (HDD), a CD-ROM, etc. The input/output device 1040 may include an input device (e.g., a keyboard, a keypad, a mouse, etc.) and an output device (e.g., a printer, a display device, etc.). The power supply 1050 supplies operation voltages for the computing system 2000.

The image sensor 1060 may communicate with the SOC 1010 via the buses or other communication links. As described above, the image sensor 1060 may be integrated with the SOC 1010 in one chip, or the image sensor 1060 and the SOC 1010 may be implemented as separate chips.

The components in the electronic device 1000 may be packaged in various forms, such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flat pack (TQFP), small outline IC (SOIC), shrink small outline package (SSOP), thin small outline package (TSOP), system in package (SIP), multi chip package (MCP), wafer-level fabricated package (WFP), or wafer-level processed stack package (WSP).

The electronic device 1000 may be any computing system including at least one SOC. For example, the electronic device 1000 may include a digital camera, a mobile phone, a smart phone, a portable multimedia player (PMP), a personal digital assistant (PDA), etc.

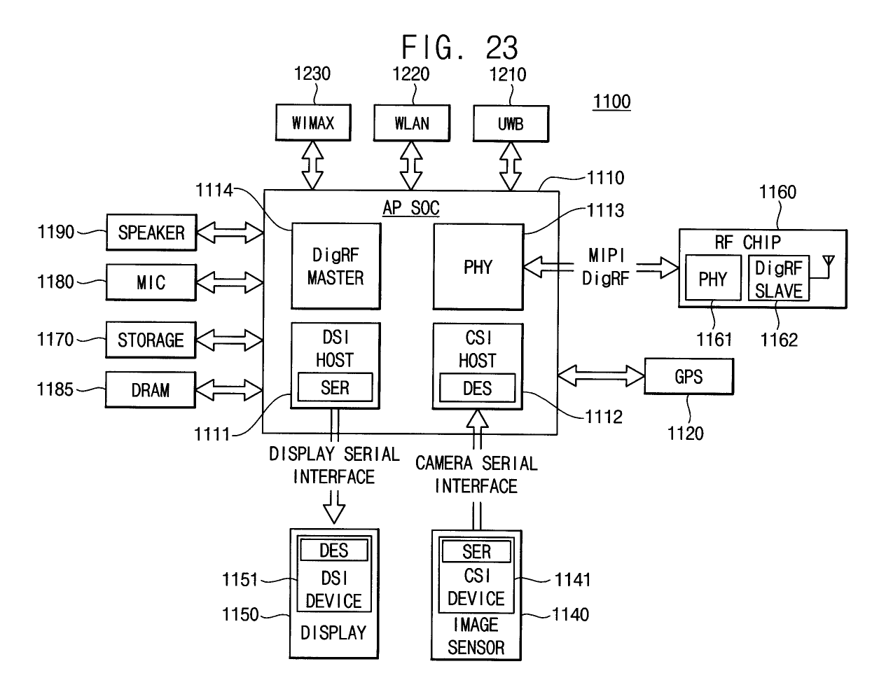

FIG. 23 is a block diagram illustrating an interface employable in the electronic device of FIG. 22 according to example embodiments.

Referring to FIG. 23, an electronic device 1100 may be implemented by a data processing device that uses or supports a mobile industry processor interface (MIPI) interface. The computing system 1100 may include an SOC 1110 in a form of an application processor (AP), an image sensor 1140, a display device 1150, etc.

A CSI host 1112 of the SOC 1110 may perform a serial communication with a CSI device 1141 of the image sensor 1140 via a camera serial interface (CSI). In some embodiments, the CSI host 1112 may include a deserializer (DES), and the CSI device 1141 may include a serializer (SER). A DSI host 1111 of the SOC 1110 may perform a serial communication with a DSI device 1151 of the display device 1150 via a display serial interface (DSI).

In some example embodiments, the DSI host 1111 may include a serializer (SER), and the DSI device 1151 may include a deserializer (DES). The electronic device 1100 may further include a radio frequency (RF) chip 1160 performing a communication with the SOC 1110. A physical layer (PHY) 1113 of the electronic device 1100 and a physical layer (PHY) 1161 of the RF chip 1160 may perform data communications based on a MIPI DigRF. The SOC 1110 may further include a DigRF MASTER 1114 that controls the data communications of the PHY 1161.

The electronic device 1100 may further include a global positioning system (GPS) 1120, a storage 1170, a MIC 1180, a DRAM device 1185, and a speaker 1190. In addition, the electronic device 1100 may perform communications using an ultra wideband (UWB) 1120, a wireless local area network (WLAN) 1220, a worldwide interoperability for microwave access (WIMAX) 1130, etc. However, the structure and the interface of the electric device 1100 are not limited thereto.

The example embodiments described above may be applied to arbitrary devices and systems that require the signal transfer. Particularly the example embodiments may be efficiently applied to mobile devices and systems that require a smaller size, a higher operational speed and lower power consumption.

The foregoing is illustrative of example embodiments and is not to be construed as limiting thereof. Although a few example embodiments have been described, those skilled in the art will readily appreciate that many modifications are possible in the exemplary embodiments without materially departing from the novel teachings and advantages of the present disclosure. Accordingly, all such modifications are intended to be included within the scope of the present disclosure as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A receiver circuit comprising:
a first p-channel metal oxide semiconductor (PMOS) transistor configured to apply a power supply voltage to a power node in response to a clock signal;
an input circuit coupled to the power node, and configured to receive the power supply voltage, the input circuit including a plurality of PMOS transistors configured to generate a first sensing signal in response to an input signal and configured to generate a second sensing signal in response to at least one reference signal; and
an amplifier configured to amplify the first sensing signal and the second sensing signal and to generate a first output signal representing a first of two binary values, and to generate a second output signal representing a second of the two binary values opposite to the first binary values.

2. The receiver circuit of claim 1, further comprising:
a ground termination circuit including a resistor coupled between a first node and a ground voltage, the first node configured to receive the input signal.

3. The receiver circuit of claim 2, wherein the input circuit includes:
a second PMOS transistor coupled between the power node and a first node configured to generate the first sensing signal, a gate of the second PMOS transistor configured to receive the input signal; and
a third PMOS transistor coupled between the power node and a second node configured to generate the second sensing signal, a gate of the third PMOS transistor configured to receive a first reference signal.

4. The receiver circuit of claim 2,
wherein the at least one reference signal includes a plurality of reference signals, and
wherein the receiver further comprises a reference voltage generation circuit configured to generate the plurality of reference signals to have voltage levels different from each other.

5. The receiver circuit of claim 2,
wherein the at least one reference signal includes a first reference signal and a second reference signal, and
wherein the receiver further comprises a reference voltage generation circuit configured to generate the first and second reference signals, the first reference signal having a voltage level higher than a predetermined voltage level, and the second reference signal having a voltage level lower than the predetermined voltage level.

6. The receiver circuit of claim 5, wherein the input circuit is configured to generate the first sensing signal and the second sensing signal based on the input signal and the first reference signal when the input signal has a first voltage level corresponding to a ground voltage and based on the input signal and the second reference signal when the input signal has a second voltage level higher than the first voltage level and lower than the power supply voltage.

7. The receiver circuit of claim 2,
wherein the at least one reference signal includes a first reference signal and a second reference signal, and
wherein the receiver further comprises a reference voltage generation circuit configured to generate the first and second reference signals, the second reference signal being lower than the first reference signal, a voltage level of the first reference signal and a voltage level of the second reference signal being between the ground voltage and the power supply voltage.

8. The receiver circuit of claim 1, wherein the input circuit includes:
a second PMOS transistor coupled between the power node and a first node configured to generate the first sensing signal, a gate of the second PMOS transistor configured to receive the input signal;
a third PMOS transistor coupled between the power node and a second node configured to generate the second sensing signal, a gate of the third PMOS transistor configured to receive the first reference signal;
a fourth PMOS transistor coupled between the power node and the first node, a gate of the fourth PMOS transistor configured to receive the input signal; and
a fifth PMOS transistor coupled between the power node and the second node, a gate of the fifth PMOS transistor configured to receive the second reference signal.

9. The receiver circuit of claim 2, wherein the amplifier includes:
a latch circuit coupled between the power supply voltage and a ground node, the latch circuit including a latch node and an inversion latch node configured to provide the first output signal and the second output signal, respectively;
a switching n-channel metal oxide semiconductor (NMOS) transistor configured to apply the ground voltage to the ground node in response to an inverted clock signal;
a first NMOS transistor coupled between the ground voltage and a first node configured to receive the first sensing signal, a gate of the first NMOS transistor configured to receive the clock signal;
a second NMOS transistor coupled between the ground voltage and a second node configured to receive the second sensing signal, a gate of the second NMOS transistor configured to receive the clock signal;
a first PMOS transistor coupled between the power supply voltage and the latch node, a gate of the first PMOS transistor configured to receive the first sensing signal; and
a second PMOS transistor coupled between the power supply voltage and the inversion latch node, a gate of the second PMOS transistor configured to receive the second sensing signal.

10. The receiver circuit of claim 2, wherein the amplifier includes:
a latch circuit coupled between a first node receiving the first sensing signal, a second node configured to receive the second sensing signal and the ground voltage, the latch circuit including a latch node and an inversion latch node configured to provide the first output signal and the second output signal, respectively;
a first NMOS transistor coupled between the ground voltage and the latch node, a gate of the first NMOS transistor configured to receive the clock signal; and
a second NMOS transistor coupled between the ground voltage and the inversion latch node, a gate of the second NMOS transistor configured to receive the clock signal.

11. The receiver circuit of claim 2, further comprising:
a post-amplifier configured to amplify the first output signal and the second output signal, and to generate a third output signal to have voltage levels at the power supply voltage and the ground voltage.

12. A system comprising:
a transmitter circuit including a transmission driver configured to drive a first node in response to a pull up signal and a pull down signal; and
a receiver circuit configured to receive an input signal at a terminal that is coupled to the first node through a signal line, the receiver circuit including:
a switching p-channel metal oxide semiconductor (PMOS) transistor configured to apply a power supply voltage to a power node in response to a clock signal;
an input circuit coupled to the power node, and configured to receive the power supply voltage, the input circuit including a plurality of PMOS transistors configured to generate a first sensing signal and a second sensing signal in response to the input signal and at least one reference signal, the first sensing signal corresponding to the input signal, the second sensing signal corresponding to the at least one reference signal; and
an amplifier configured to amplify the first sensing signal and the second sensing signal, and to generate a first output signal and a second output signal opposite to the first output signal.

13. The system of claim 12, further comprising:
a ground termination circuit including a resistor coupled between the terminal and a ground voltage,
wherein the transmitter circuit is configured to drive the first node such that the input signal swings between a first voltage level and a second voltage level higher than the first voltage level, the first voltage level corresponding to the ground voltage, and the second voltage level being lower than the power supply voltage.

14. The system of claim 13, wherein the receiver circuit further includes:
a reference voltage generator configured to generate the at least one reference signal including a first reference signal and a second reference signal lower than the first reference signal, wherein voltage levels of the first and second reference signals are between the power supply voltage and ground voltage.

15. The system of claim 13, wherein the transmitter circuit further includes:
a first reference driver configured to provide a first reference signal to the receiver circuit; and
a second reference driver configured to provide a second reference signal lower than the first reference signal to the receiver circuit.

16. A semiconductor device comprising:
a first PMOS transistor configured to apply a power supply voltage to a first node in response to a clock signal;
a second PMOS transistor coupled to the first node and configured to generate a first sensing signal at a second node in response to an input signal;
a third PMOS transistor coupled to the first node and configured to generate a second sensing signal at a third node in response to a first reference signal;
a first amplifier configured to amplify the first and second sensing signals, and to generate first and second output signals in response to the first and second sensing signals, respectively,
wherein the first output signal has a voltage representing a first binary values and the second output signal has a voltage representing a second binary values, opposite of the first binary values.

17. The device of claim 16, further comprising:
a fourth PMOS transistor coupled to the first node and configured to generate the first sensing signal at the second node in response to the input signal; and
a fifth PMOS transistor coupled to the first node and configured to generate the second sensing signal at the third node in response to a second reference signal lower than the first reference signal.

18. The device of claim 17, further comprising:
a transmitter configured to generate the input signal to comprise a first voltage level and a second voltage level lower than the first voltage level, the first and second voltage levels representing different binary values, and
a reference voltage generation circuit configured to generate the first reference signal and the second reference signal.

19. The device of claim 18, wherein a voltage level of the first reference signal is the same as or lower than the first voltage level of the input signal and a voltage level of the second reference signal is the same as or higher than the second voltage level of the input signal.

20. The device of claim 17, further comprising:
a second amplifier configured to amplify the first output signal and the second output signal, and to generate a third output signal to have voltage levels at the power supply voltage and the ground voltage.
